(19) United States
(12) Patent Application Publication
(10) Pub. No.: US 2018/0245950 A1
(43) Pub. Date: Aug. 30, 2018

(54) PLANARIZED CAPACITIVE SENSOR ARRAY

(71) Applicant: Maxim Integrated Products, Inc., San Jose, CA (US)

(72) Inventor: Sudarsan Uppili, Portland, OR (US)

(21) Appl. No.: 15/902,453

(22) Filed: Feb. 22, 2018

Related U.S. Application Data
(60) Provisional application No. 62/464,644, filed on Feb. 28, 2017.

(51) Int. Cl. G01D 5/24; H03K 17/96; H03K 17/955

(52) U.S. Cl. CPC G01D 5/2405; G06F 3/044; H03K 17/955; H03K 17/962

(57) ABSTRACT

A capacitive sensor element includes a substrate with a metal pillar disposed upon on the substrate. The metal pillar includes a first end that faces towards the substrate and a second end that faces away from the substrate. An encapsulant is disposed upon the substrate, covering at least one side portion of the metal pillar and extending beyond the second end of the metal pillar. A metal plug is disposed in a cavity defined within the encapsulant. The cavity is defined proximate to the second end of the metal pillar, and the metal plug is in contact with the second end of the metal pillar. The capacitive sensor element also includes a dielectric layer disposed upon the encapsulant, such that the dielectric layer covers the cavity.

### CROSS-REFERENCE TO RELATED APPLICATIONS

The present application claims the benefit under 35 U.S.C. § 119(e) of U.S. Provisional Application Ser. No. 62/464,644, filed Feb. 28, 2017, and titled “PLANARIZED CAPACITIVE SENSOR ARRAY,” which is incorporated herein by reference in its entirety.

### BACKGROUND

Capacitive sensor arrays are employed in electronic devices, such as mobile devices, human-interface devices, and test equipment. For example, a capacitive sensor array can be used to detect objects in proximity to (e.g., in contact with or near) the capacitive sensor array. Capacitive sensor arrays generally function in one of two ways. Some capacitive sensors detect changes in mutual capacitance between row and column electrodes that can be affected by the proximity of an object (e.g., a finger or stylus) to the row and column electrodes. Other capacitive sensors detect changes in self-capacitance of conductive elements (e.g., metal panels), where the proximity of an object to a conductive element can affect the parasitic capacitance of the conductive element. Self-capacitance based capacitive sensor arrays are gaining importance because they can be easier to implement in small electronic devices (e.g., medical test strips or fingerprint detectors).

### BRIEF DESCRIPTION OF THE DRAWINGS

The detailed description is described with reference to the accompanying figures. The use of the same reference numbers in different instances in the description and the figures may indicate similar or identical items. Various embodiments or examples (“examples”) of the present disclosure are disclosed in the following detailed description and the accompanying drawings. The drawings are not necessarily to scale. In general, operations of disclosed processes may be performed in an arbitrary order, unless otherwise provided in the claims.

FIG. 1 is a diagrammatic partial cross-sectional side elevation view illustrating a sensor package including a planarized capacitive sensor array, in accordance with an example implementation of the present disclosure.

FIG. 2 is a diagrammatic partial cross-sectional side elevation view illustrating a capacitive sensor element of a sensor package including a planarized capacitive sensor array, such as the sensor package illustrated in FIG. 1, in accordance with an example implementation of the present disclosure.

FIG. 3 is a diagrammatic top view illustrating a planarized capacitive sensor array of a sensor package, such as the sensor package illustrated in FIG. 1, in accordance with an example implementation of the present disclosure.

FIG. 4 is a diagrammatic end view illustrating an electronic device that includes a sensor package, such as the sensor package illustrated in any of FIGS. 1 through 3, in accordance with an example implementation of the present disclosure.

FIG. 5A is a flow diagram illustrating an example process for fabricating a sensor package including a planarized capacitive sensor array, such as the sensor package illustrated in FIG. 1.

FIG. 5B is a flow diagram illustrating a portion of an example process for fabricating a sensor package including a planarized capacitive sensor array, such as the sensor package illustrated in FIG. 1.

FIG. 5C is a flow diagram illustrating a portion of an example process for fabricating a sensor package including a planarized capacitive sensor array, such as the sensor package illustrated in FIG. 1.

FIG. 6A is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6B is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6C is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6D is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6E is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6F is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6G is a diagrammatic partial cross-sectional side elevation view illustrating the fabrication of a sensor package including a planarized capacitive sensor array, such as the sensor package illustrated in FIG. 1, in accordance with the process shown in FIG. 5A.

FIG. 6H is a diagrammatic partial cross-sectional side elevation view illustrating the fabrication of a sensor package including a planarized capacitive sensor array, such as the sensor package illustrated in FIG. 1, in accordance with the process shown in FIG. 5A.

### DETAILED DESCRIPTION

### Overview

Electronic devices (e.g., mobile devices, human-interface devices, or test equipment) often include capacitive sensor arrays. For example, an electronic device can employ a capacitive sensor array in an input system (e.g., a touch screen, touch panel, touchpad, or the like), a biometric input system (e.g., a fingerprint detector), a proximity sensor, an imaging device (e.g., scanner), or a fluid analyzer (e.g., to analyze biological fluid samples or other fluid samples). Example mobile devices include, but are not limited to, smartphones, tablets, smartwatches, digital cameras, notebook computers, media players, portable gaming devices, and the like. Example human-interface devices include, but are not limited to, touchpads, touch screens, touch panels, keyboards, buttons, switches, fingerprint detectors, and combinations thereof. Example test equipment includes, but is not limited to, medical test strips, micro-fluid cassettes, scanners (e.g., scanning beds or scanning pads), lab on a chip (LOC) devices, and so forth.

It is often desirable for capacitive sensor arrays to have planar sensing surfaces. For example, in medical applications planar sensing surfaces can mitigate buildup of contaminants from previous tests, where fluid or particles may otherwise become lodged in between capacitive sensor elements. A sensor package is disclosed that includes a planarized capacitive sensor array. A method of fabricating a sensor package that includes a planarized capacitive sensor array is also disclosed.

### Example Implementations

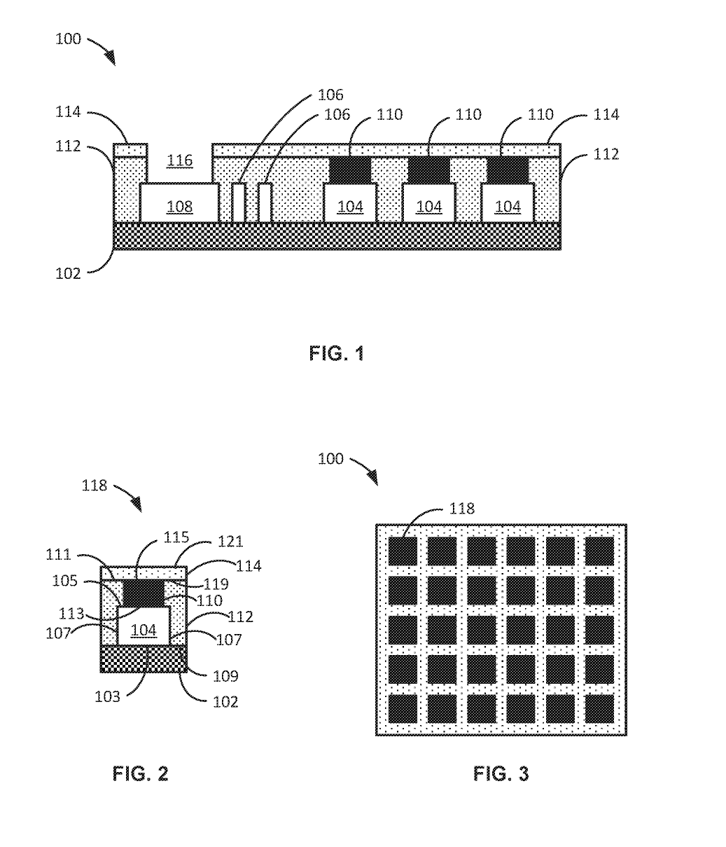

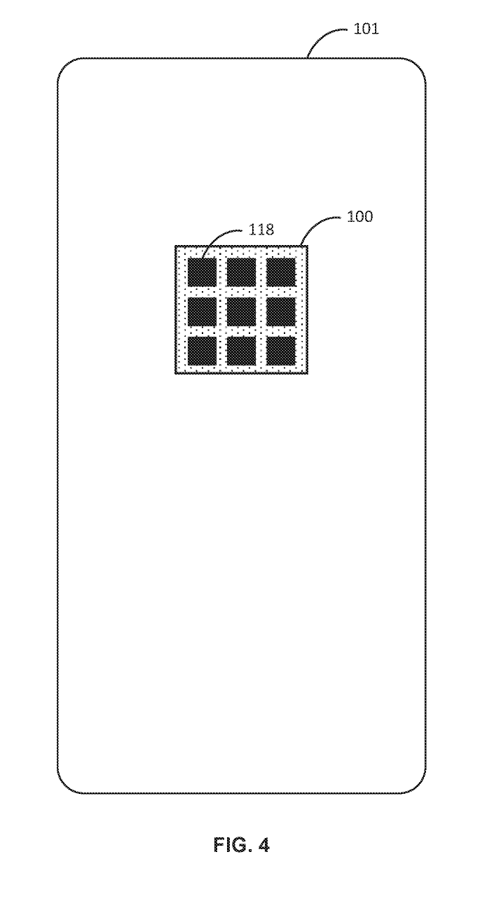

FIGS. 1 through 4 show embodiments of a sensor package 100 that can be employed in an electronic device 101. In an embodiment, the electronic device 101 is a mobile device. For example, the mobile device can include, but is not limited to, a smartphone, a tablet, a smartwatch, a digital camera, a notebook computer, a media player, a portable gaming device, or the like. In another embodiment, the electronic device 101 is a human-interface device. For example, the human-interface device can include, but is not limited to, a touchpad, a touch screen, a touch panel, a keyboard, a button, a switch, a fingerprint detector, or a combinations thereof. In yet another embodiment, the electronic device 101 includes test equipment. For example, the test equipment can include a medical test strip, a micro-fluid cassette, a scanner (e.g., a scanning bed or scanning pad), a lab on a chip (LOC) device, or the like.

The sensor package 100 described herein includes a planarized capacitive sensor array including one or more capacitive sensor elements 118 disposed upon a substrate 102 (e.g., a silicon wafer). The sensor package 100 can include a capacitive sensor array of any size (e.g., any number of capacitive sensor elements 118 arranged in an array).

The sensor package 100 incudes at least one metal pillar 104 disposed upon the substrate 102. In an embodiment, the metal pillar 104 is formed from a metal layer (e.g., an Aluminum or Copper layer) that is exposed by etching one or more layers on the substrate 104. For example, the metal layer can be exposed by performing a wet or dry etching process on the substrate 102. In other embodiments, the metal pillar 104 can be disposed upon the substrate 102 by adhering a pre-fabricated metal pillar to the substrate 102, sputtering the metal pillar 104 onto the substrate 102, or performing an additive deposition process (e.g., 3D printing the metal pillar 104 onto the substrate 102). The metal pillar 104 has a first end 103 that faces towards the substrate 102 and a second end 105 that faces away from the substrate 102.

A plurality of metal pillars 104 can be disposed upon the substrate 102 to form a plurality of capacitive sensor elements 118. For example, the capacitive sensor array can include a single capacitive sensor element 118 (e.g., as shown in FIG. 2), a linear arrangement of capacitive sensor elements 118 (e.g., as shown in FIG. 1), or an N×M matrix of capacitive sensor elements 118 (e.g., as shown in FIG. 3), where N and M can be any combination of same (e.g., N=M) or different (e.g., N≠M) real numbers.

An encapsulant 112 is disposed upon the substrate 102. The encapsulant 112 covers at least one side portion 107 of the metal pillar 104 and extends beyond the second end 105 of the metal pillar 104. In some embodiments, the encapsulant 112 covers all side portions 107 of the metal pillar 104. For example, the encapsulant 112 can cover portions of the metal pillar 104 other than the first end 103 and the second end 105. In some embodiments, the encapsulant 112 can also cover at least a portion of the first end 103 and/or the second end 105. The encapsulant 112 includes a first surface 109 that faces towards the substrate 102 and a second surface 111 that faces away from the substrate. The second surface 111 of the encapsulant 112 can be planarized. The encapsulant 112 can include any insulator material. For example, in an embodiment, the encapsulant 112 includes an oxide layer (e.g., a Silicon Dioxide layer).

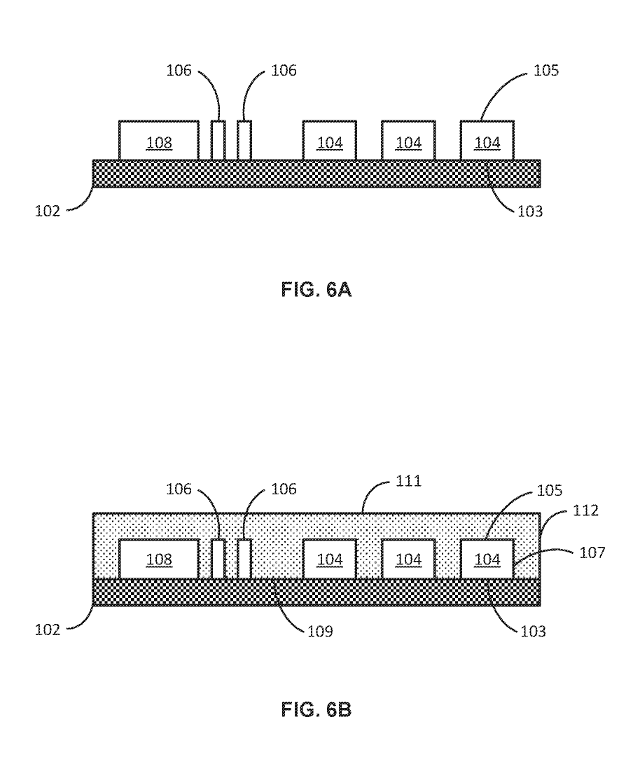

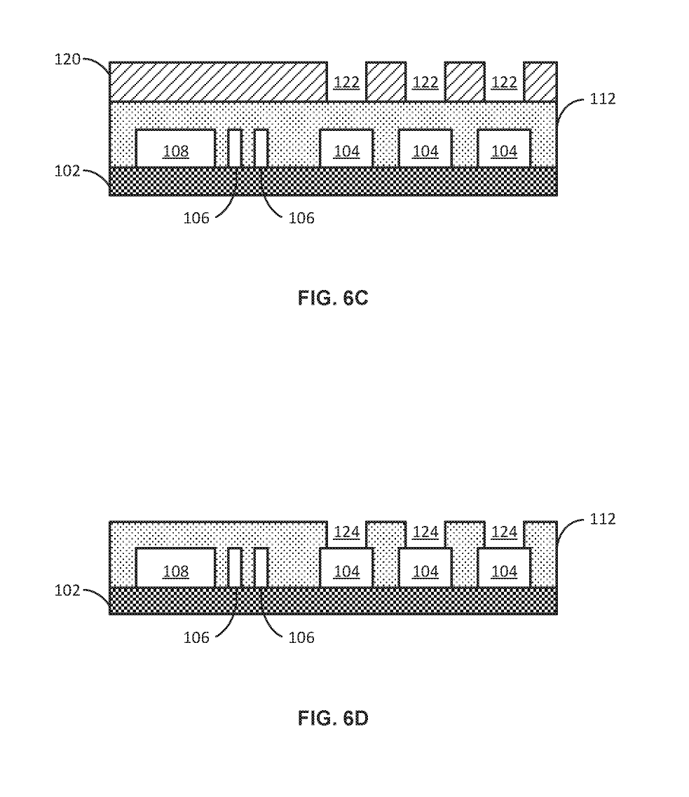

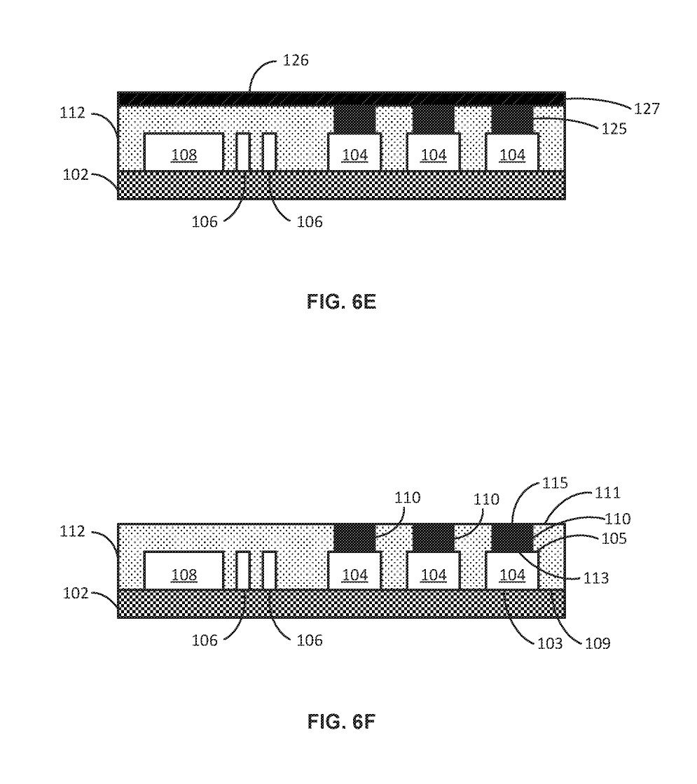

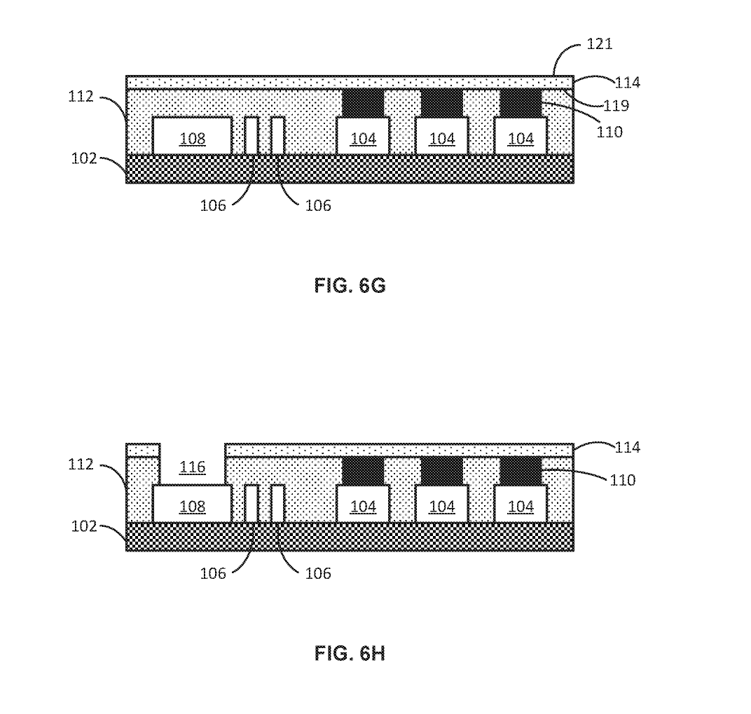

As shown in FIG. 6D, the encapsulant 112 includes at least one cavity 124 defined within the encapsulant 112. For example, the cavity 124 can be defined in the second surface 111 of the encapsulant 111. The cavity 124 is defined in proximity to the second end 105 of the metal pillar 104. Referring again to FIGS. 1 and 2, a metal plug 110 is disposed within the cavity 124 and in contact with the second end 105 of the metal pillar 104. In embodiments, the metal plug 110 is made of Tungsten or a Tungsten alloy. Tungsten can provide for improved resistance to corrosion. The metal plug 110 can also be made from other metals (e.g., Copper). The metal plug 110 and the metal pillar 104 are assembled separately (e.g., disposed upon the substrate 102 by different processing steps) and can include different metals.

In some embodiments, the metal plug 110 and the metal pillar 104 can also have different dimensions. For example, the metal pillar 104 can be wider than the metal plug 110. In an embodiment, the metal plug 110 and the metal pillar 104 can have respective widths in the range of 0.1 microns to 5 microns. Widths in the range of 0.1 microns to 5 microns can prevent unwanted dishing of the metal plug 110. In an embodiment, the metal plug 110 can have a depth in the range of 10 nanometers to 1000 nanometers. The metal plug 110 and the metal pillar 104 can have any dimensions; however, the foregoing ranges are provided by way of example.

The metal plug 110 includes a first end 113 and a second end 115. In an embodiment, the second end 115 of the metal plug 110 is flush with the second surface 111 of the encapsulant 112. For example, the second end 115 of the metal plug 110 and the second surface 111 of the encapsulant 112 can both be planarized. In some embodiments, a plurality of metal plugs 110 are disposed in respective cavities 124 that are defined within the encapsulant 112. For example, a metal pillar 104 can have a respective metal plug 110 disposed within a respective cavity 124, in proximity to the metal pillar 104 such that the first end 113 of the metal plug 110 is in contact with the second end 105 of the metal pillar 104.

The sensor package 100 further includes a dielectric layer 114 disposed upon the encapsulant 112. The dielectric layer 114 covers the cavities 124 having the metal plugs 110 disposed therein. In this manner, one or more capacitive sensor elements 118 are defined, wherein a capacitive sensor element 118 includes a respective metal pillar 104 and metal plug 110 disposed in between the substrate 102 and the dielectric layer 114. The dielectric layer 114 can be planarized to achieve a capacitive sensor element 118 or a planarized capacitive sensor array (e.g., including a plurality of capacitive sensor elements 118). In an embodiment, the dielectric layer 114 can have a thickness in the range of 1 nanometer to 100 nanometers. The dielectric layer 114 can be of any thickness; however, the foregoing range is provided by way of example. The dielectric layer 114 can include any dielectric material. For example, in an embodiment, the dielectric layer 114 includes a nitride layer (e.g., a Silicon Nitride layer).

In embodiments, the encapsulant 112 fills spaces between the substrate 102 and the dielectric layer 114 that are not occupied by a metal pillar 104 or a metal plug 110, thereby providing structural support for each capacitive sensor element 118. In this regard, an array of capacitive sensor elements 118, such as the linear array shown in FIG. 1 or the matrix shown in FIG. 3, can be made planar without having to sacrifice structural soundness of the sensor package 100.

The sensor package 100 can also include one or more circuit components 106 disposed upon the substrate 102. For example, circuit components 106 can include, but are not limited to, connector pins, metal traces, resistors, transistors, capacitive elements, inductive elements, and combinations thereof In some embodiments, circuit components 106 include at least one metal trace for connecting to at least one metal pillar 104. In an embodiment, the sensor package 100 further includes at least one electronic component 108 disposed upon the substrate 102. For example, the electronic component 108 can include a die, a controller (e.g., ASIC, micro-processor, or the like), a sensor chip, any combination thereof, and so forth. At least one opening 116 can be defined within sensor package 100 structure for accessing the electronic component 108 and/or circuit components 106. For example, the opening 116 can be formed by removing a portion of the dielectric layer 114 and the encapsulant 112 to provide an access window in proximity to the electronic component 108 and/or circuit components 106.

### Example Process

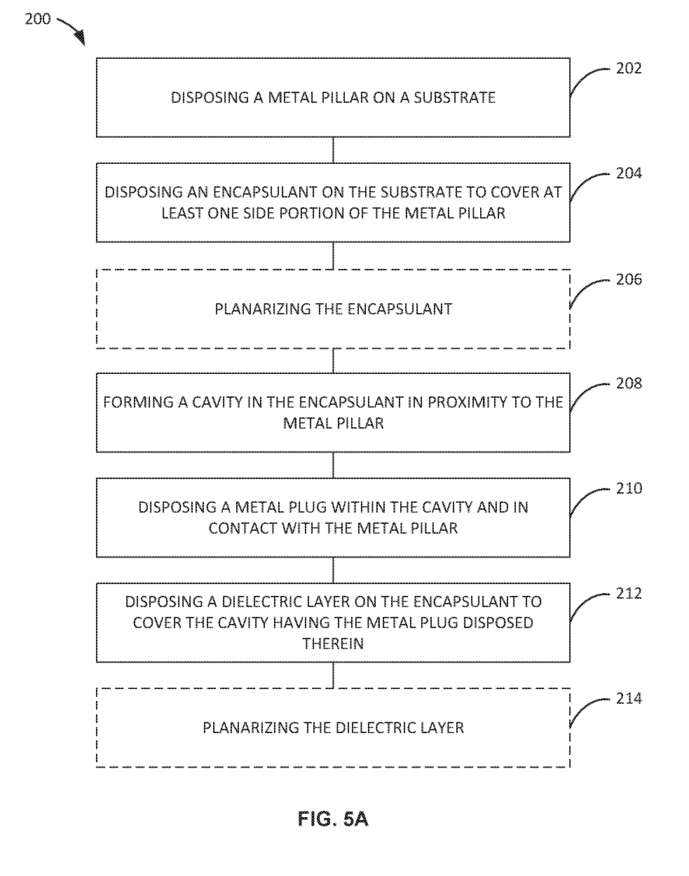

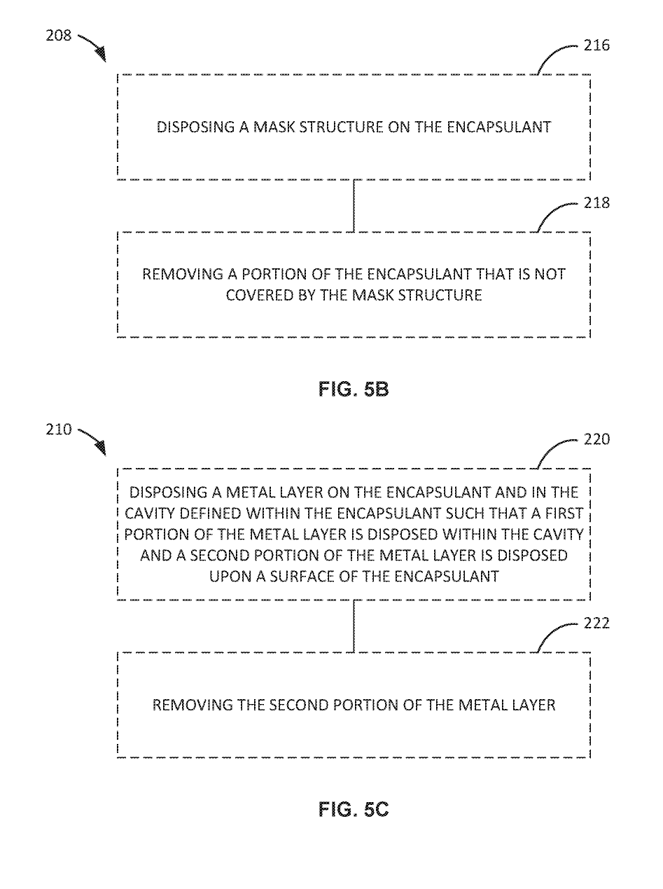

FIGS. 5A through 5C illustrate an example process 400 that employs techniques to fabricate a sensor package, such as the sensor package 100 shown in FIGS. 1 through 3. FIGS. 6A through 6H illustrate a section of a sensor package (e.g., the sensor package 100 shown in FIGS. 1 through 3), during fabrication. In general, operations of disclosed processes (e.g., process 400) may be performed in an arbitrary order, unless otherwise provided in the claims.

In the process 200 illustrated in FIG. 5A, at least one metal pillar 104 is disposed upon the substrate 102 (block 202). In an implementation shown in FIG. 6A, at least one metal pillar 104 is formed or otherwise placed on the substrate 102 in a perpendicular configuration (e.g., metal 104 extends away from the substrate 102). In one implementation, the metal pillar 104 is formed from a metal layer (e.g., an Aluminum or Copper layer) that is exposed by etching one or more layers on the substrate 104. For example, the metal layer can be exposed by performing a wet or dry etching process on the substrate 102. In another implementation, disposing metal pillars 104 on the substrate 102 can include using a pick-and-place and bonding operation to place individual metal pillars 104 on the substrate 102. A metal pillar 104 can also be disposed upon the substrate 102 by sputtering the metal pillar 104 onto the substrate 102, or performing an additive deposition process (e.g., 3D printing the metal pillar 104 onto the substrate 102). In some implementations, at least one electronic component 108 and/or at least one circuit component 106 can also be disposed upon the substrate 102.

An encapsulant 112 is then disposed upon the substrate 102 (block 204). The encapsulant 112 can include any insulator material. For example, in an embodiment, the encapsulant 112 includes an oxide layer (e.g., a Silicon Dioxide layer). The encapsulant can be disposed upon the substrate 102 using a flow process, where the encapsulant 112 is disposed upon the substrate 102 in a liquid or semi-solid form and then hardened by a cooling or curing process. As shown in FIG. 6B, the encapsulant 112 covers at least one side portion 107 of the metal pillar 104 and extends beyond the second end 105 of the metal pillar 104. In some implementations, the encapsulant 112 is disposed upon the substrate 102 such that the encapsulant covers an entirety of the metal pillar 104. For example, the encapsulant 112 can cover side portions of the metal pillar 107 and the second end 105 of the metal pillar 104. Optionally, the second surface 111 of the encapsulant 112 can be planarized after the encapsulant 112 is disposed upon the substrate 102 (block 206). For example, the encapsulant 112 can be planarized by performing a chemical mechanical polishing/planarization (CMP) process or the like.

At least one cavity 124 is defined within the encapsulant 112 (block 208). For example, the cavity 124 can be defined in the second surface 111 of the encapsulant 111. In an implementation shown in FIG. 5B, at least one cavity 124 is defined within the encapsulant 112 by disposing a mask structure 120 on the encapsulant 112 (block 216) and removing a portion of the encapsulant 112 that is not covered by the mask structure 120 to form the cavity 124 (block 218). As shown in FIG. 6C, the mask structure 120 can include at least one opening 122 configured to form a respective cavity 124 in the encapsulant 112. For example, the mask structure 120 can include a photomask, where a portion of the encapsulant 112 below the opening 122 is removed by a photo-etching process. In some implementations, other etching processes can be used, for example, chemical etching processes. In other implementations, a laser or mechanical etching process can be used to remove selected portions of the encapsulant 112. The cavity 124 is defined in proximity to the second end 105 of the metal pillar 104 (e.g., as shown in FIG. 6D).

Referring again to FIG. 5A, a metal plug 110 is disposed within the cavity 124 and in contact with the second end 105 of the metal pillar 104. In an implementation shown in FIG. 5C, at least one metal plug 110 is disposed within a respective cavity 124 by disposing a metal layer 126 on the encapsulant 112 (block 220). In some implementations, the metal layer 126 is made of Tungsten or a Tungsten alloy. For example, the metal layer 126 can be disposed upon the encapsulant 112 by performing a Tungsten chemical vapor deposition (CVD) process (e.g., a Ti/TiN+CVD Tungsten deposition process). The metal layer 126 covers a surface (e.g., second surface 111) of the encapsulant 112 and fills the cavity 124. For example, as shown in FIG. 6E, the metal layer 126 includes a first portion 125 that fills the cavity 124 to form the metal plug 110 and a second portion 127 that covers at least a portion of the second surface 111 of the encapsulant 112. The second portion 127 of the metal layer 126 can be removed (block 222), thereby leaving only the first portion 125 (i.e., the metal plug 110) that is disposed within the cavity 124 (e.g., as shown in FIG. 6F). For example, the second portion 127 of the metal layer 126 can be removed by etching and/or planarizing the metal layer 126, such as by performing a CMP process or the like. In an implementation, the metal plug 110 and/or the encapsulant 112 can be planarized so that the second end 115 of the metal plug 110 is made flush with the second surface 111 of the encapsulant 112.

A dielectric layer 114 is then disposed upon the encapsulant 112 (block 212). As shown in FIG. 6G, the dielectric layer 114 covers the cavities 124 having the metal plugs 110 disposed therein. In this manner, one or more capacitive sensor elements 118 are defined, wherein a capacitive sensor element 118 includes a respective metal pillar 104 and metal plug 110 disposed in between the substrate 102 and the dielectric layer 114. The dielectric layer 114 can be planarized to achieve a planarized capacitive sensor element 118 or a planarized capacitive sensor array with a plurality of capacitive sensor elements 118 (block 214). The dielectric layer 114 can include any dielectric material. For example, the dielectric layer 114 can be a nitride layer (e.g., a Silicon Nitride layer).

In an implementation shown in FIG. 6H, at least one opening 116 can be defined within sensor package 100 structure for accessing the electronic component 108 and/or circuit components 106. For example, the opening 116 can be formed by removing a portion of the dielectric layer 114 and the encapsulant 112 to provide an access window in proximity to the electronic component 108 and/or circuit components 106. The opening 116 can be defined by placing a mask structure (e.g., a photomask) over the dielectric layer 114 and performing an etching process (e.g., photo-etching) to remove portions of the dielectric layer 114 and the encapsulant 112 which are not covered by the mask structure. In other implementations, a laser or mechanical etching process can be used to remove selected portions of the dielectric layer 114 and the encapsulant 112.

It is to be understood that the present application is defined by the appended claims. Although embodiments of the present application have been illustrated and described herein, it is apparent that various modifications may be made by those skilled in the art without departing from the scope and spirit of this disclosure.

What is claimed is:

1. A capacitive sensor element, comprising:
a substrate;
a metal pillar disposed upon on the substrate, the metal pillar having a first end that faces towards the substrate and a second end that faces away from the substrate;
an encapsulant disposed upon the substrate, wherein the encapsulant covers at least one side portion of the metal pillar and extends beyond the second end of the metal pillar;
a metal plug disposed in a cavity defined within the encapsulant, wherein the cavity is defined proximate to the second end of the metal pillar, and the metal plug is in contact with the second end of the metal pillar; and
a dielectric layer disposed upon the encapsulant, wherein the dielectric layer covers the cavity.

2. The capacitive sensor element of claim 1, wherein the metal pillar includes a first metal, and the metal plug includes a second metal that is different from the first metal.

3. The capacitive sensor element of claim 1, wherein the encapsulant includes a first surface that faces towards the substrate and a second surface that faces away from the substrate, wherein the second surface of the encapsulant is planarized.

4. The capacitive sensor element of claim 3, wherein the metal plug includes a first end that is in contact with the second end of the metal pillar and a second end that faces away from the metal pillar, wherein the second end of the metal plug is planarized.

5. The capacitive sensor element of claim 4, wherein the second end of the metal plug is flush with the second surface of the encapsulant.

6. The capacitive sensor element of claim 1, wherein the dielectric layer is planarized.

7. The capacitive sensor element of claim 1, wherein the encapsulant comprises an oxide layer.

8. The capacitive sensor element of claim 1, wherein the dielectric layer comprises a nitride layer.

9. The capacitive sensor element of claim 1, wherein the metal plug comprises at least one of Tungsten or Copper.

10. A sensor package, comprising:
a substrate; and
a capacitive sensor array, the capacitive sensor array including:
a plurality of metal pillars disposed upon on the substrate, wherein a metal pillar of the plurality of metal pillars has a first end that faces towards the substrate and a second end that faces away from the substrate;
an encapsulant disposed upon the substrate, wherein the encapsulant covers at least one side portion of the metal pillar and extends beyond the second end of the metal pillar;
a plurality of metal plugs disposed in respective cavities of a plurality of cavities defined within the encapsulant, wherein a cavity of the plurality of cavities is defined proximate to the second end of the metal pillar, and a metal plug of the plurality of metal plugs is disposed in the cavity and in contact with the second end of the metal pillar; and
a dielectric layer disposed upon the encapsulant, wherein the dielectric layer covers the respective cavities of the plurality of cavities defined within the encapsulant.

11. The sensor package of claim 10, wherein the metal pillar includes a first metal, and the metal plug includes a second metal that is different from the first metal.

12. The sensor package of claim 10, wherein the encapsulant includes a first surface that faces towards the substrate and a second surface that faces away from the substrate, wherein the second surface of the encapsulant is planarized.

13. The sensor package of claim 12, wherein the metal plug includes a first end that is in contact with the second end of the metal pillar and a second end that faces away from the metal pillar, wherein the second end of the metal plug is planarized.

14. The sensor package of claim 13, wherein the second end of the metal plug is flush with the second surface of the encapsulant.

15. The sensor package of claim 10, wherein the dielectric layer is planarized.

16. The sensor package of claim 10, further comprising:
an electronic component disposed upon the substrate, wherein the encapsulant covers at least one side portion of the of the electronic component, wherein an opening is defined within the encapsulant and within the dielectric layer for accessing the electronic component.

17. A method, comprising:
disposing a metal pillar on a substrate, the metal pillar having a first end that faces towards the substrate and a second end that faces away from the substrate;
disposing an encapsulant on the substrate, wherein the encapsulant covers at least one side portion of the metal pillar and extends beyond the second end of the metal pillar;
forming a cavity in the encapsulant, wherein the cavity is formed proximate to the second end of the metal pillar;
disposing a metal plug in the cavity and in contact with the second end of the metal pillar; and
disposing a dielectric layer on the encapsulant, wherein the dielectric layer covers the cavity.

18. The method of claim 17, wherein forming the cavity in the encapsulant includes:
disposing a mask structure on the encapsulant, the mask structure including an aperture that extends over a portion of the encapsulant; and
removing the portion of the encapsulant to form the cavity.

19. The method of claim 17, wherein disposing the metal plug in the cavity and in contact with the second end of the metal pillar includes:
disposing a metal layer on the encapsulant and in the cavity defined within the encapsulant, wherein the metal plug is formed by a first portion of the metal layer that is disposed in the cavity;
removing a second portion of the metal layer other than the first portion of the metal layer, thereby leaving the metal plug disposed in the cavity.

20. The method of claim 17, further comprising:
planarizing the dielectric layer.
